(19) United States
(12) Patent Application Publication
(10) Pub. No.: US 2024/0361695 A1
(43) Pub. Date: Oct. 31, 2024

(54) STRUCTURES INCLUDING A SiOCN PHOTORESIST ADHESION LAYER AND METAL-OXIDE RESIST AND METHODS OF FORMING SAME

(71) Applicant: ASM IP Holding B.V., Almere (NL)

(72) Inventors: João Ricardo Antunes Afonso, Tokyo (JP); Yiting Sun, Leuven (BE); Fanyong Ran, Tokyo (JP); Jerome Samuel Nicolas, Tokyo (JP); Zecheng Liu, Tokyo (JP)

(21) Appl. No.: 18/644,370

(22) Filed: Apr. 24, 2024

Related U.S. Application Data
(60) Provisional application No. 63/462,386, filed on Apr. 27, 2023.

(51) Int. Cl. G03F 7/16; G03F 7/004; G03F 7/075

(52) U.S. Cl. CPC G03F 7/167; G03F 7/0043; G03F 7/0751; G03F 7/0755

(57) ABSTRACT

Methods of forming structures including an adhesion layer and structures including the adhesion layer are disclosed. The adhesion layer may include nitrogen. The method can include forming a metal oxide resist overlying and in contact with the adhesion layer. Exemplary methods further include forming the photoresist underlayer.

### CROSS-REFERENCE TO RELATED APPLICATIONS

This application claims priority to U.S. Provisional Patent Application Ser. No. 63/462,386 filed Apr. 27, 2023 and titled STRUCTURES INCLUDING A SiOCN PHOTORESIST ADHESION LAYER AND METAL-OXIDE RESIST AND METHODS OF FORMING SAME, the disclosure of which is hereby incorporated by reference in its entirety.

### FIELD OF INVENTION

The present disclosure generally relates to structures and to methods of forming structures using photoresist. More particularly, the disclosure relates to structures including a photoresist adhesion layer and to methods of forming such structures.

### BACKGROUND OF THE DISCLOSURE

During the manufacture of electronic devices, fine patterns of features can be formed on a surface of a substrate by patterning the surface of the substrate and etching material from the substrate surface using, for example, gas-phase etching processes. As a density of devices on a substrate increases, it becomes increasingly desirable to form features with smaller dimensions.

Photoresist is often used to pattern a surface of a substrate prior to etching. A pattern can be formed in the photoresist by applying a layer of photoresist to a surface of the substrate, masking the surface of the photoresist, exposing the unmasked portions of the photoresist to radiation, such as ultraviolet light, and removing a portion (e.g., the unmasked or masked portion) of the photoresist, while leaving a portion of the photoresist on the substrate surface.

High-numerical aperture (High-NA) extreme ultraviolet (EUV) lithography can provide relatively high resolution for smaller pitch patterns. However, such lithography generally uses a relatively thin photoresist (PR) film and a relatively thin carbon hard mask (CHM) film. Work on chemically amplified resists (CARs) showed that thinner PR film induced an increase in line-edge and line-width roughness (LER/LWR). Recently, metal oxide resist (MOR) is attracting attention. Compared to traditional organic CAR, MOR exhibits better resolution on both line/space and pillar patterning, and better local critical dimension (CD) uniformity (LCDU) on pillar patterns. The better resolution should extend single patterning methods which, in turn, will reduce process complexities and costs. Robust refractory metal oxide etching barriers make MOR better for pattern transfer for smaller features and for thinner resists, and provide for better etch durability and sensitivity. MOR is thought to be the most suitable candidate PR for High-NA EUV lithography. However, there are still several challenges, including metal contamination control, CD control, and defect control, when considering use of MOR.

Accordingly, improved methods and structures suitable for forming fine patterns of features on a surface of a substrate are desired.

Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

Various embodiments of the present disclosure relate to a method of forming a structure comprising an adhesion layer, and more particularly, to a method of forming a structure that includes or is suitable for use with a metal oxide resist (MOR). While the ways in which various embodiments of the present disclosure address drawbacks of prior methods are discussed in more detail below, in general, various embodiments of the disclosure provide a method that includes use of a photoresist adhesion layer to promote adhesion between, for example, a carbon hard mask (CHM) and a MOR. The adhesion layer can be nonmetallic to mitigate metal contamination, and can have tunable surface properties, such that the adhesion layer can be used with a variety of MOR. Further, the adhesion layer may have relatively high etch selectivity to an underlying layer, such as silicon oxide—e.g., compared to, for example, a silicon oxycarbide photoresist underlayer. Yet further, the inclusion of nitrogen in the adhesion layer can increase a source of secondary electrons during a lithography process, which may allow for a reduced dose of radiation during an exposure step of the lithography process.

In accordance with examples of the disclosure, a method of forming a structure comprising an adhesion layer includes providing a substrate comprising a substrate surface within a reaction chamber and forming an adhesion layer using a (e.g., first) cyclic deposition process overlying the substrate surface. The steps of forming the adhesion layer can include providing a silicon precursor to the reaction chamber, providing one or more of an inert and a nitrogen-containing reactant gas into the reaction chamber, and forming a plasma to form activated species that react with the silicon precursor or a derivative thereof to form the adhesion layer. In some cases, the silicon precursor includes nitrogen. In some cases, the silicon precursor may not include nitrogen—i.e., the silicon precursor can include a nitrogen-free precursor. The adhesion layer can include silicon, oxygen, carbon, and nitrogen. In accordance with further examples, the method can include forming a metal oxide resist (MOR) overlying the adhesion layer. Exemplary methods can further include forming a photoresist underlayer overlying the substrate, wherein the photoresist underlayer is interposed between the substrate surface and the adhesion layer. The underlayer can include, for example, an oxide, nitride, or oxynitride. The photoresist underlayer can be formed using a second cyclic deposition process.

In accordance with exemplary embodiments of the disclosure, a structure is formed using a method described herein.

In accordance with further examples of the disclosure, a system for forming an adhesion layer is provided. Exemplary systems include a reaction chamber, a silicon precursor source fluidly coupled to the reaction chamber, an inert and/or nitrogen gas source fluidly coupled to the reaction chamber, and a controller configured to perform a method as described herein or a portion thereof.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a cyclical deposition process in accordance with exemplary embodiments of the disclosure.

FIG. 3 illustrates another cyclical deposition process in accordance with exemplary embodiments of the disclosure.

FIG. 4 illustrates a structure in accordance with exemplary embodiments of the disclosure.

FIG. 5 illustrates a system configured for executing a method as described herein.

FIG. 6 illustrates a system in accordance with yet additional examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood that the invention extends beyond the specifically disclosed embodiments and/or uses thereof and obvious modifications and equivalents thereof. Thus, it is intended that the scope of the invention disclosed should not be limited by the particular disclosed embodiments described below.

The present disclosure generally relates to methods of forming a structure that includes an adhesion layer and to structures including an adhesion layer. As described in more detail below, exemplary methods can be used to form structures suitable for use with or that include a metal oxide resist (MOR). Use of an adhesion layer as described herein can reduce defects that can otherwise occur during lithography and can mitigate metal contamination that can otherwise arise when using metal underlayers. Further, use of adhesion layers as described herein can provide for relatively high etch selectivity—e.g., compared to underlayers that do not include nitrogen, which improves pattern transfer, particularly for high aspect ratio patterns or features. Yet further, use of the adhesion layers described herein can reduce an amount of radiation required during an exposure step of a lithography process and thus can increase throughput of a manufacturing process.

As used herein, the term substrate may refer to any underlying material or materials including and/or upon which one or more layers can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can additionally or alternatively include various features, such as recesses, lines, and the like formed within or on at least a portion of a layer of the substrate. In accordance with examples of the disclosure, the substrate can include a carbon hard mask (CHM) on a surface.

In some embodiments, film refers to a layer extending in a direction perpendicular to a thickness direction. In some embodiments, layer refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

In this disclosure, gas may include material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution assembly, such as a showerhead, other gas distribution device, or the like, may be used for, e.g., sealing the reaction space, and may include a seal gas, such as a rare gas.

In some cases, such as in the context of deposition of material, the term precursor can refer to a compound that participates in the chemical reaction that produces another compound, and particularly to a compound that constitutes a film matrix or a main skeleton of a film, whereas the term reactant can refer to a compound, in some cases other than precursors, that activates a precursor, modifies a precursor, or catalyzes a reaction of a precursor; a reactant may provide an element (such as O, N, and/or C) to a film matrix and become a part of the film matrix. In some cases, the terms precursor and reactant can be used interchangeably. The term inert gas refers to a gas that does not take part in a chemical reaction to an appreciable extent and/or a gas that excites or cleaves a precursor when, for example, RF or microwave power is applied, but unlike a reactant, it may not become a part of a film matrix to an appreciable extent.

The term cyclic deposition process or cyclical deposition process may refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component, and of which can be plasma enhanced.

The term atomic layer deposition may refer to a vapor deposition process in which deposition cycles, typically a plurality of consecutive deposition cycles, are conducted in a process chamber. Generally, for ALD processes, during each cycle, a precursor is introduced to a reaction chamber and is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas or an inert gas) may subsequently be introduced into the process chamber for use in converting the chemisorbed precursor to the desired material on the deposition surface. The reactant/inert gas can be capable of further reaction or interaction with the precursor. Purging steps can be utilized during one or more cycles, e.g., during each step of each cycle, to remove any excess precursor from the process chamber and/or remove any excess reactant and/or reaction byproducts from the reaction chamber.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” and related words can refer independently to “typically or broadly comprising,” “comprising,” “consisting essentially of,” or “consisting of” in some embodiments. In accordance with aspects of the disclosure, any defined meanings of terms do not necessarily exclude ordinary and customary meanings of the terms.

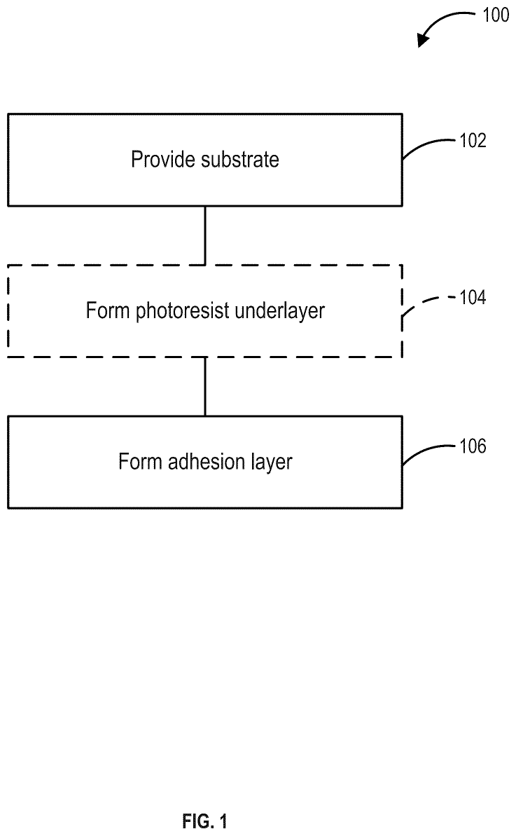

Turning now to the figures, FIG. 1 illustrates a method 100 of forming a structure comprising an adhesion layer in accordance with exemplary embodiments of the disclosure. Method 100 includes the steps of providing a substrate (step 102), optionally forming a photoresist underlayer (step 104), and forming an adhesion layer (step 106).

Step 102 includes providing a substrate, such as a substrate described herein. The substrate can include one or more layers, including one or more material layers, to be etched. By way of examples, the substrate can include a deposited oxide, a native oxide, or an amorphous carbon layer to be etched and a carbon hardmask. The substrate can include several layers underlying the material layer(s) to be etched.

During step 104, a photoresist underlayer is formed on a surface of the substrate. The photoresist underlayer can be formed using a variety of techniques, including spin-on, chemical vapor deposition, and cyclical process techniques. Plasma-processed SiO and SiOC materials have been identified as promising candidates for photoresist underlayer material due to their capabilities of continuously thinner thickness and lower dry etching rates compared with the conventional spin-on-glass (SoG). Typically, PEALD is suggested as a method for a superior (lower) non-uniformity (% NU) of the film thickness.

In accordance with exemplary aspects of method 100, the photoresist underlayer is formed using a cyclical deposition process, such as an ALD process—e.g., PEALD. The cyclical deposition process can include use of activated species (e.g., formed from one or more of precursor(s), reactant(s), or and/or inert gas(es)) that are formed using one or more of a direct plasma and a remote plasma. Alternatively, step 104 can include a thermal cyclical deposition process. Use of cyclical deposition processes may be desirable, because they allow for the formation of a photoresist underlayer with desired thickness—e.g., less than 10 nm or less than or about equal to 5 nm, with improved thickness uniformity-both within a substrate and from substrate-to-substrate. Using a plasma-enhanced process may be desirable, because plasma-enhanced processes allow for deposition of the photoresist underlayer material at relatively low temperatures and/or relatively high rates-compared to thermal processes.

In accordance with examples of the disclosure, a temperature within a reaction chamber during step 104 can be less than 500° C., less than 300° C., less than 100° C. or between about 50° C. and about 500° C., or about 150° C. and about 300° C. A pressure within the reaction chamber during step 104 can be about 1 Torr to about 100 Torr, about 2 Torr to about 20 Torr, or about 3 Torr to about 10 Torr.

In accordance with exemplary embodiments of the disclosure, step 104 includes forming or depositing one or more of a silicon or metal oxide, a silicon or metal nitride, and a silicon or metal oxynitride. Such oxides, nitrides, and/or oxynitrides can also include carbon.

The photoresist underlayer can include, for example, one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride. The metal can include, for example, one or more metals selected from the group consisting of titanium, tantalum, tungsten, tin, and hafnium. In some cases, the photoresist underlayer includes carbon. The carbon can be incorporated into the photoresist underlayer as the photoresist underlayer is deposited and/or a carbon treatment can be applied to a surface of the photoresist underlayer. Additionally or alternatively, a carbon-containing layer or other layer can be deposited onto a surface of the photoresist underlayer. A thickness of the photoresist underlayer can be less than 10 nm, less than 5 nm, or greater than 0 nm and less than 10 nm.

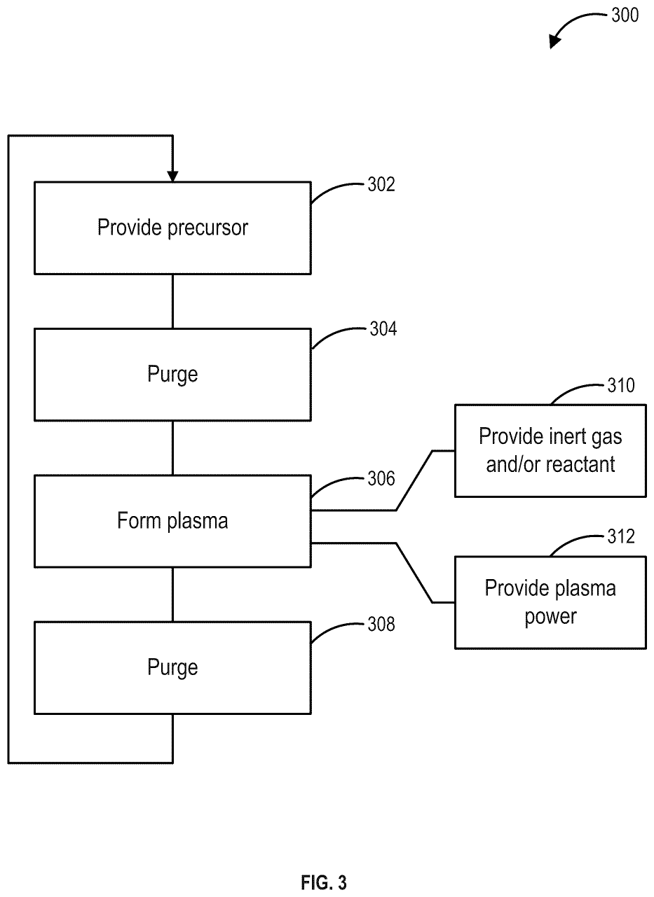

A cyclical process 300 for forming the photoresist underlayer suitable for step 104 is illustrated in FIG. 3. Cyclical process 300 can include (A) pulsing a first precursor comprising a metal or silicon into a reaction chamber (step 302), and (B) pulsing or continuously providing a reactant (e.g., an oxidant and/or nitriding agent and/or an inert gas) into the reaction chamber (step 310). In the illustrated example, cyclical process 300 also includes forming a plasma (step 306) by providing a plasma power (step 312) to form a plasma. Cyclical process 300 can also include purging the reaction chamber (steps 304, 306). During purge steps 304, 306, any excess precursor and/or reactants and/or any reaction byproducts can be purged from the reaction chamber. The purge can be performed by supplying an inert gas to the reaction chamber and/or using a vacuum source. Cyclical process 300 can be repeated—e.g., between about 10 and about 50 or about 200 and about 500 times, before method 100 proceeds to step 106. The cyclic deposition process 300 can be a plasma-enhanced atomic layer deposition process.

In some cases, the cyclical process for forming the photoresist underlayer can include (A) pulsing a precursor comprising a metal into a reaction chamber, (B) pulsing or continuously providing a reactant (e.g., comprising an oxidant and/or nitriding agent and/or inert gas) into the reaction chamber, and (C) pulsing a carbon precursor into the reaction chamber. One or more of the pulses can be separated by a purge step. Further, each pulsing step or a combination of pulsing steps (e.g., pulsing steps (A) and (B)) can be repeated a number of times prior to proceeding to the next step to tune a composition of the photoresist underlayer. For example, a range of ratios of (AB):C can be about 1:1 to about 1:10. Unless otherwise noted, steps (A) and (B) or steps (A), (B), and (C) can be performed in any order and various combinations of the steps can be repeated.

In accordance with exemplary aspects of the disclosure, a precursor comprising silicon is provided during step 302. In some cases, the silicon precursor can also include carbon. Exemplary silicon precursors suitable for use in forming a photoresist underlayer include silicon precursors noted below in connection with step 202.

In accordance with other exemplary aspects of the disclosure, the precursor comprises a metal. In these cases, the precursor can include a transition metal, such as one or more metals selected from the group consisting of titanium, tantalum, tungsten, tin, and hafnium. The precursor comprising a metal can also include carbon—e.g., one or more organic groups bonded directly or indirectly to a metal atom. By way of particular examples, the precursor comprising a metal can include a metal halide or a metal organic compound, or an organometallic compound, such as one or more of tetrakis(dimethylamino)titanium (TDMAT), titanium isopropoxide (TTIP), titanium chloride (TiCl), tetrakis(ethylmethylamino)hafnium (TEMAHf), hafnium chloride (HfCl), trimethylaluminum (TMA), triethylaluminium (TEA), other metal halide, or other metal-containing compounds.

The reactant can include an oxidizing reactant, a nitriding reactant, or a reducing agent, such as a hydrogen-containing reactant. The oxidizing and/or nitriding reactant include reactants that include one or more of oxygen and nitrogen. In some cases, the reactant can include both nitrogen and oxygen. And, in some cases, the two or more oxidizing and/or nitriding reactants can be included in a single pulse or in a continuous flow. Exemplary oxidizing and nitriding agents include oxygen (O₂), water (H₂O), ozone (O₃), hydrogen peroxide (H₂O₂), ammonia (NH₃), diazene (N₂H₂), CO₂, nitrous oxide (N₂O); exemplary hydrogen-containing reactants include hydrogen (H₂), and the like.

As noted above, the oxidizing and/or nitriding reactant can be exposed to a (e.g., direct) plasma during step 306/312 to form excited species for use in a PEALD process or cyclical plasma process. A power to form the plasma during step 312/306 can be about 20 W to about 1000 W. A frequency of the power to form the plasma can be between about 200 kHz and about 2.45 GHz. A duration of step 312 can be between about 0.01 and about 5 seconds.

When used, the carbon precursor can include any suitable organic compound, such as compounds comprising carbon and oxygen. In some cases, the carbon precursor can also include nitrogen. The carbon precursor can be selected to react with, for example an —OH terminated surface of metal oxides and/or a —NH₂ terminated surface of a metal nitride. Examples of suitable carbon precursors include one or more of organic compounds, such as acid anhydrate (e.g., an acetic anhydrate), toluene, diethylene glycol, triethylene glycol, acetaldehyde, and organosilicon compounds, such as silanes, and siloxanes. Exemplary organosilicon compounds include (n,n-dimethylamino)trimethylsilane, trimethoxy(octadecyl)silane, hexamethyldisilazane, trimethoxy(3,3,3-trifluoropropyl)silane, trimethoxyphenylsilane, trichloro(3,3,3-trifluoropropyl)silane and hexamethyldisilazane.

Once the photoresist underlayer is formed, an adhesion layer is formed during step 106. Step 106 can be performed in situ-within the same reaction chamber and without an air and/or a vacuum break.

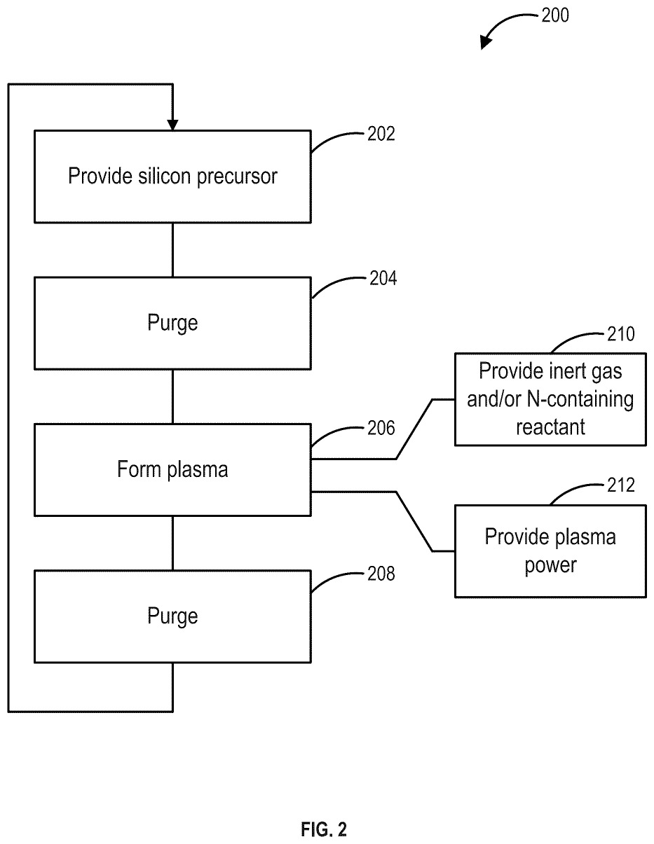

FIG. 2 illustrates an exemplary cyclical deposition process 200 for forming an adhesion layer. Cyclical deposition process 200 includes pulsing or providing a silicon precursor to a reaction chamber (step 202), purging any unreacted precursor and/or byproducts (step 204), providing one or more of an inert and a nitrogen-containing reactant gas into the reaction chamber (step 210), and forming a plasma using the inert and/or the nitrogen-containing reactant and providing plasma power (step 212) to form a plasma (step 206) that generates activated species that react with the silicon precursor or a derivative thereof to form the adhesion layer, and purging any excess reactive species and/or byproducts from the reaction chamber (step 208). As illustrated, steps 202-208 can be repeated—e.g., between about 5 and about 50 or about 200 or about 500 times. The temperature and pressure during step 106 can be the same or similar for step 102 and/or 104.

During step 202, a silicon precursor is provided to the reaction chamber. In accordance with examples of the disclosure, the silicon precursor comprises nitrogen. In some cases, silicon precursor is nitrogen-free. When the silicon precursor is a nitrogen-free precursor, the reactant may include nitrogen, such that the adhesion layer comprises silicon, oxygen, carbon, and nitrogen.

In accordance with further examples, the silicon precursor consists of or consists essentially of Si, C, H, and O, or Si, C, H, O, and N, which may be provided to the reaction chamber with the aid of a carrier gas. By way of examples, the silicon precursor can be selected from one or more of the group consisting of:

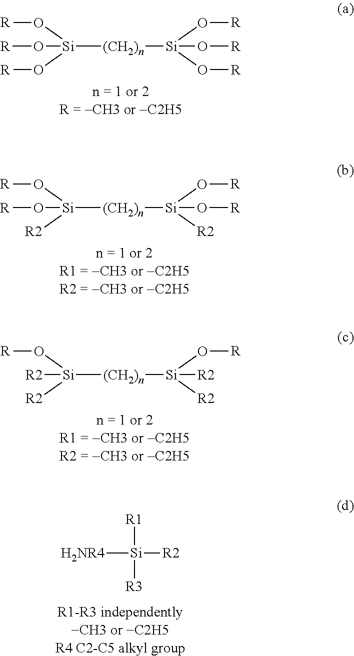

In accordance with further examples, the silicon precursor is selected from one or more of the group consisting of: 3-methoxypropyltrimethoxysilane, bis(trimethoxysilyl)methane, 1,2 bis(methyldimethoxysilyl)ethane, 1,2-bis(triethoxysilyl)ethane, 1,2-bis(triethoxysilyl)ethene, 1,2-bis(diethoxymethylsilyl)ethane, 1,2-bis(trimethoxysilyl)ethane, 1,1,3,3-tetramethoxy-1,3-disilacyclobutane, 1,1,3,3-tetraethoxy-1,3-disilacyclobutane, 1,1,3,3,5,5-hexamethoxy-1,3,5-trisilacyclohexane, 1,1,3,3,5,5-hexaethoxy-1,3,5-trisilacyclohexane, and 3-(trimethoxysilyl)propylamine. By way of particular examples, the silicon precursor can be or include 3-methoxypropyltrimethoxysilane or 3-(trimethoxysilyl)propylamine. A flowrate of the silicon precursor during step 202 can be between about 100 sccm and about 150 sccm. A duration of step 202 can be between about 0.1 s and about 0.3 s. In accordance with examples of the disclosure, the silicon precursor used during process 300 (step 104) is the same as the silicon precursor used during process 200 (step 106). In other cases, the silicon precursors can be different.

During step 204, any excess silicon precursor and/or any reaction byproducts can be purged from the reaction chamber. The purge can be performed by supplying an inert gas to the reaction chamber and/or using a vacuum source.

During step 206, a plasma is formed using an inert gas and/or a nitrogen-containing reactant gas. The inert gas can be or include one or more of Ar, He, Ne, Kr, Xe, O₂, CO, CO₂, CₓH_{y}, and H₂ or their mixture. The nitrogen-containing reactant gas can be or include N₂, N₂O, NH₃ or their mixture. A flowrate of the one or more of an inert gas and a nitrogen-containing reactant gas can be between about 5 and about 100 sccm or between about 0.1 and about 10 slm.

A power to form the plasma during step 206/212 can be about 20 W to about 1000 W. A duration of step 312 can be between about 0.01 s and about 5 s. A frequency of the power to form the plasma can be between about 200 kHz and about 2.45 GHz.

During step 208, the plasma power is switched off and any excess reactive species and/or byproducts are purged. Steps 202-208 can be repeated a number of times to form a silicon-based adhesion layer of a desired thickness—e.g., greater than 0 and less than about 2 nm.

Methods in accordance with the disclosure can also include a step of forming a photoresist layer overlying and in contact with the adhesion layer. In accordance with examples of the disclosure, the photoresist layer is or includes a metal oxide resist (MOR). Exemplary MOR materials include oxides of tin, titanium, tantalum, indium, and/or zirconium The MOR can be deposited using, for example, spin-on techniques or vapor deposition techniques. A thickness of the MOR can be greater than 0 and less than 100 nm.

Table 1 below illustrates particular process conditions, which illustrate that an amount of nitrogen and carbon in the adhesion layer can be controlled by controlling process conditions. The precursor used in the examples of Table 1 was a nitrogen free precursor and the reactant was nitrogen (N₂).

| | Pressure | RF Power | Rf on | N₂ flow | Purge | thickness | | | | | |
|---|---|---|---|---|---|---|---|---|---|---|---|
| Run | [PA] | [W] | [seconds] | [SLM] | [SLM] | [nm] | % NU | SFE D | SFE P | % C | % N |
| 1 | 800 | 175 | 1.1 | 1 | 0.4 | 1.8 | 1.59 | 34.7 | 26.9 | 10.2 | 10.5 |
| 2 | 300 | 300 | 2 | 5 | 0.4 | 1.9 | 1.48 | 32.7 | 35.2 | 3.2 | 6.2 |
| 3 | 700 | 100 | 0.2 | 1 | 0.4 | 2.0 | 0.97 | 34.5 | 24.1 | 15.4 | 6.1 |
| 4 | 300 | 50 | 0.2 | 1 | 0.8 | 1.4 | 1.96 | 36.5 | 20.7 | 9.0 | 9.6 |
| 5 | 800 | 150 | 0.2 | 2.5 | 0.6 | 2.4 | 1.28 | 35.9 | 25 | 13.8 | 13.3 |

As observed by this table, one can control the nitrogen content and the carbon content, having samples with high carbon and low nitrogen on the one hand and on the other hand having both high carbon and nitrogen.

These analyses from XPS consider a depth up to 10 nm, so it has to be considered that the actual nitrogen and carbon content will be much higher, since our layers have 1.4 to 2.4 nm. In any case, a relative elemental composition can be inferred.

By using a nitrogen plasma in this way, we are able to show the introduction of relevant nitrogen content, without the extinction of the carbon in the layer that promotes adhesion. It also has an advantage in relation to using a different precursor, since this allows for easier processing (the using same precursor for both the adhesion layer and the underlayer) and higher shown nitrogen content.

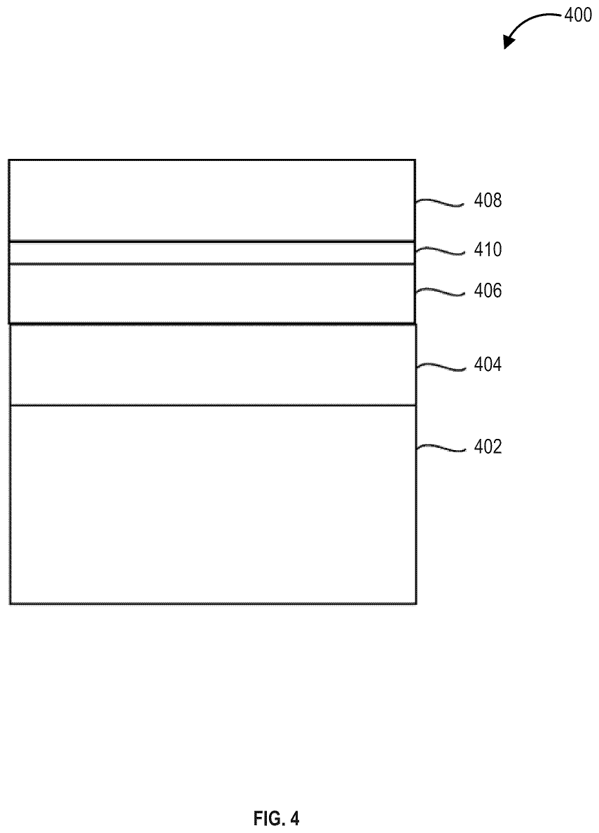

FIG. 4 illustrates a structure 400 in accordance with exemplary embodiments of the disclosure. Structure 400 can be formed using, for example, method 100.

As illustrated, structure 400 includes a substrate 402, a material layer 404, a photoresist underlayer 406, a photoresist layer 408, and an adhesion layer 410 interposed between and in contact with photoresist underlayer 406 and photoresist layer 408.

Substrate 402 can include a substrate as described above. By way of examples, substrate 402 can include a semiconductor substrate, such as a bulk material, such as silicon (e.g., single-crystal silicon), other Group IV semiconductor material, Group III-V semiconductor material, and/or Group II-VI semiconductor material and can include one or more layers (e.g., a patterning stack) overlying the bulk material. Further, as noted above, substrate 402 can include various topologies, such as recesses, lines, and the like formed within or on at least a portion of a layer of the substrate.

Material layer 404 can be patterned and etched using a photoresist underlayer and a layer of photoresist as described herein. Exemplary materials suitable for material layer 404 include, for example, oxides, such as native oxides or field oxides. Other exemplary material layer 404 materials include a carbon hard mask, amorphous carbon, nitrides, other oxides, silicon, and add-on films (e.g., a self-assembled monolayer (e.g., hexamethyldisilazane (HMDS)).

Photoresist underlayer 406 can include a photoresist underlayer formed in accordance with a method described herein (e.g., method 100/process 300) and/or have properties and/or material as described herein. Exemplary photoresist underlayers include one or more of a silicon or metal oxide, a silicon or metal nitride, and a silicon or metal oxynitride-any of which can include or not include carbon. For example, photoresist underlayer 406 can include one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride.

A thickness of photoresist underlayer 406 can depend on a composition of material layer 404, a thickness of material layer 404, a type of photoresist, and the like. In accordance with examples of the disclosure, photoresist underlayer 406 has a thickness of less than 10 nm or less than or about 5 nm or between about 0.1 nm and about 10 nm.

Adhesion layer 410 desirably exhibits good adhesion and other properties as described herein. As noted above, in accordance with examples of the disclosure, adhesion layer 410 includes nitrogen. In accordance with examples of the disclosure, the adhesion layer comprises silicon, oxygen, carbon, and nitrogen. A thickness of the adhesion layer can be greater than 0 nm and less than 2 nm.

To provide desired adhesion between photoresist layer 408 and photoresist underlayer 406, adhesion layer 410 may have or be tuned to have desired surface chemistry properties, e.g., quantified as surface energy, which is further categorized into a polar part of surface energy and a disperse part of surface energy. The polar part of surface energy and the disperse part of surface energy of photoresist underlayer 406 can be calculated by measuring a contact angle of a liquid, such as water or CH₂I₂, and using the Owens, Wendt, Rabel and Kaelble (OWRK) method to determine the polar part and the disperse part of the surface energy. The same properties can be measured and calculated for photoresist layer 408.

In accordance with further examples of the disclosure, photoresist layer 408 is or includes an MOR. Exemplary MOR material and thicknesses are set forth above.

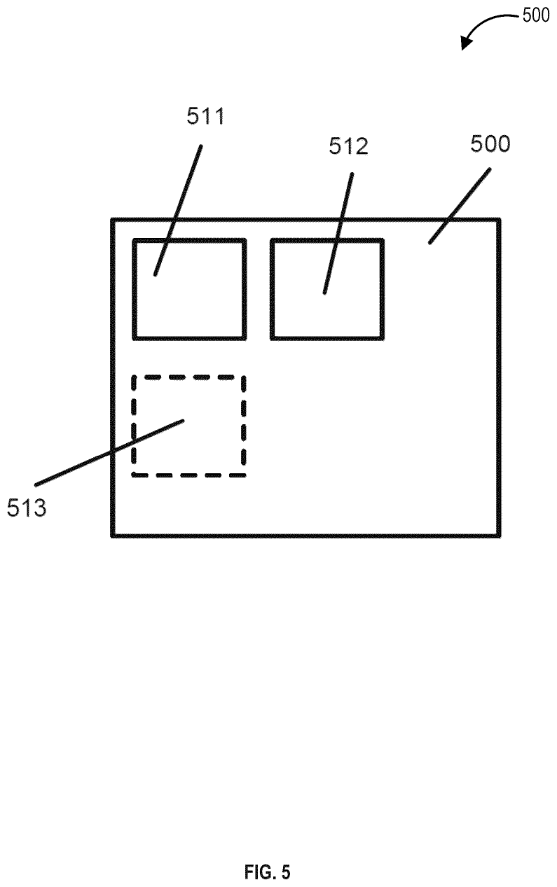

FIG. 5 illustrates a system 500 configured for executing a method as described herein. System 500 comprises at least one reaction chamber which is configured for depositing an underlayer and/or forming an adhesion layer as described herein. System 500 may comprise a first reaction chamber 511 and a second reaction chamber 512 that may both be configured for depositing an underlayer and forming an adhesion layer as described herein, or a part thereof. If desired, system 500 can include a third reaction chamber 513 in which another process, such as a thermal or plasma-enhanced post treatment, may be carried out.

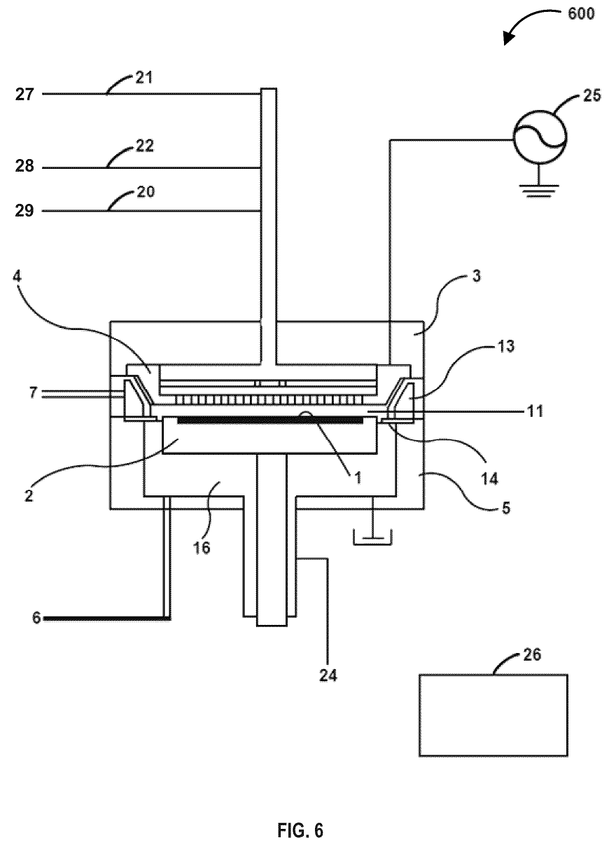

FIG. 6 illustrates an exemplary reaction system that includes a chamber suitable for use as reaction chamber 511 or 512. Reactor system 600 can be used to perform one or more steps or sub steps as described herein and/or to form one or more structures or portions thereof as described herein.

Reactor system 600 includes a pair of electrically conductive flat-plate electrodes 4, 2 in parallel and facing each other in the interior 11 (reaction zone) of a reaction chamber 3. A plasma can be excited within reaction chamber 3 by applying, for example, HRF power (e.g., 13.56 MHz or 27 MHz) from power source 25 to one electrode (e.g., electrode 4) and electrically grounding the other electrode (e.g., electrode 2). A temperature regulator can be provided in a lower stage 2 (the lower electrode), and a temperature of a substrate 1 placed thereon can be kept at a desired temperature. Electrode 4 can serve as a gas distribution device, such as a shower plate. Reactant gas, dilution gas, if any, precursor gas, and/or the like can be introduced into reaction chamber 3 using one or more of a gas line 20, a gas line 21, and a gas line 22, respectively, and through the shower plate 4. Although illustrated with three gas lines, reactor system 600 can include any suitable number of gas lines. Gas line 20 can be coupled to a silicon precursor source 29, gas line 21 can be coupled to an inert gas source 27, and gas line 22 can be coupled to another (e.g., reactant) gas source 28.

In reaction chamber 3, a circular duct 13 with an exhaust line 7 is provided, through which gas in the interior 11 of the reaction chamber 3 can be exhausted. Additionally, a transfer region 5, disposed below the reaction chamber 3, is provided with a seal gas line 24 to introduce seal gas into the interior 11 of the reaction chamber 3 via the interior 16 (transfer zone) of the transfer region 5, wherein a separation plate 14 for separating the reaction zone and the transfer zone is provided (a gate valve through which a wafer is transferred into or from the transfer region 5 is omitted from this figure). The transfer region is also provided with an exhaust line 6. In some embodiments, the deposition and treatment steps are performed in the same reaction space, so that two or more (e.g., all) of the (e.g., underlayer and adhesion layer) steps can continuously be conducted without exposing the substrate to air or other oxygen-containing atmosphere.

In some embodiments, continuous flow of an inert or carrier gas to reaction chamber 3 can be accomplished using a flow-pass system (FPS), wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber and can carry the precursor gas in pulses by switching between the main line and the detour line, without substantially fluctuating pressure of the reaction chamber.

Reactor system 600 also includes one or more controller(s) 26 programmed or otherwise configured to cause one or more method steps as described herein to be conducted. Controller(s) 26 are communicated with the various power sources, heating systems, pumps, robotics and gas flow controllers, or valves of the reactor, as will be appreciated by the skilled artisan. By way of examples, controller 26 can be configured to control gas flow of a silicon precursor and an inert gas to form an adhesion layer on a photoresist underlayer. Additionally or alternatively, the controller can be configured to perform steps to form a photoresist underlayer as described herein.

In some embodiments, a dual chamber reactor (two sections or compartments for processing wafers disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

We claim:

1. A method of forming a structure comprising an adhesion layer, the method comprising the steps of:
providing a substrate comprising a substrate surface within a reaction chamber; and
forming an adhesion layer using a first cyclic deposition process overlying the substrate surface, the steps of forming the adhesion layer comprising:
providing a silicon precursor to the reaction chamber;
providing one or more of an inert gas and a nitrogen-containing reactant gas into the reaction chamber; and
forming a plasma to form activated species that react with the silicon precursor or a derivative thereof to form the adhesion layer,
wherein the adhesion layer comprises silicon, oxygen, carbon, and nitrogen.

2. The method according to claim 1, further comprising forming a metal oxide resist (MOR) overlying the adhesion layer.

3. The method according to claim 1, further comprising forming a photoresist underlayer overlying the substrate, wherein the photoresist underlayer is interposed between the substrate surface and the adhesion layer.

4. The method according to claim 3, wherein the photoresist underlayer comprises one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride.

5. The method according to claim 4, wherein the metal comprises one or more metals selected from the group consisting of titanium, tantalum, tungsten, tin, and hafnium.

6. The method according to claim 3, wherein a thickness of the photoresist underlayer is greater than 0.1 nm and less than 10 nm.

7. The method according to claim 1, wherein the first cyclic deposition process is an atomic layer deposition process.

8. The method according to claim 1, wherein the silicon precursor comprises nitrogen.

9. The method according to claim 1, wherein the silicon precursor comprises nitrogen-free precursor.

10. The method according to claim 1, wherein the silicon precursor is selected from one or more of the group consisting of:

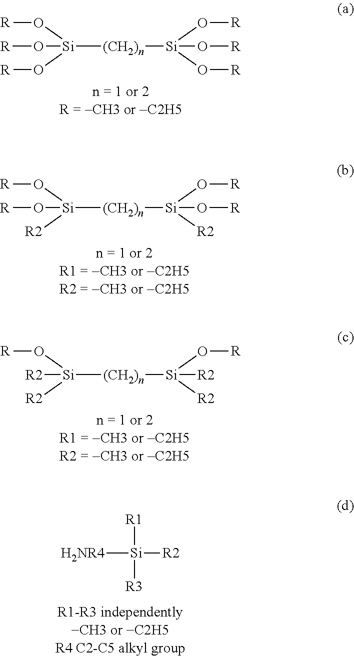

11. The method according to claim 1, wherein the silicon precursor is selected from one or more of the group consisting of: 3-methoxypropyltrimethoxysilane, bis(trimethoxysilyl)methane, 1,2 bis(methyldimethoxysilyl)ethane, 1,2-bis(triethoxysilyl)ethane, 1,2-bis(triethoxysilyl)ethene, 1,2-bis(diethoxymethylsilyl)ethane, 1,2-bis(trimethoxysilyl)ethane, 1,1,3,3-tetramethoxy-1,3-disilacyclobutane, 1,1,3,3-tetraethoxy-1,3-disilacyclobutane, 1,1,3,3,5,5-hexamethoxy-1,3,5-trisilacyclohexane, 1,1,3,3,5,5-hexaethoxy-1,3,5-trisilacyclohexane, and 3-(trimethoxysilyl)propylamine.

12. The method according to claim 3, wherein the photoresist underlayer is formed using a second cyclic deposition process.

13. The method according to claim 3, wherein the photoresist underlayer is formed using the silicon precursor.

14. The method according to claim 1, wherein a chemical formula of the silicon precursor consists of Si, C, H, O, and N.

15. The method according to claim 1, wherein the first cyclic deposition process is repeated between about 5 and about 50 or about 200 or about 500 times.

16. The method according to claim 1, wherein a thickness of the adhesion layer is greater than 0.1 nm and less than 10 nm.

17. The method according to claim 1, wherein the second cyclic deposition process is repeated between about 5 and about 50 or about 200 and about 500 times.

18. A structure formed according to the method of claim 1.

19. The structure of claim 18, wherein the photoresist underlayer comprises one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride.

20. The structure of claim 18, wherein a thickness of the adhesion layer is greater than 0.1 nm and less than about 10 nm.

21. The structure according to claim 18, further comprising the MOR overlying and in contact with the adhesion layer.
